(19) United States
(12) Patent Application Publication
(10) Pub. No.: US 2007/0199735 A1
(43) Pub. Date: Aug. 30, 2007

(54) Printed circuit board having inner via hole and manufacturing method thereof

(75) Inventors: Chi-Seong Kim, Suwon-si (KR); Hyo-Seung Nam, Suwon-si (KR); Seok-Hwan Ahn, Suwon-si (KR); Kwang-Ok Jeong, Gwangmyeong-si (KR); Kyung-Hwan Ko, Jung-gu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/709,758

(22) Filed: Feb. 23, 2007

(30) Foreign Application Priority Data
Feb. 24, 2006 (KR) 10-2006-0018219

(51) Int. Cl. H05K 1/03

(52) U.S. Cl. 174/255; 174/264; 174/262; 29/830; 29/846

(57) ABSTRACT

An aspect of the present invention features a printed circuit board. The board can comprise a core layer in which an inner via hole (IVH) is formed, a first plating layer that closes one entrance of the inner via hole, leaving a remaining space in the inner via hole unfilled; and a second plating layer that closes the other entrance of the inner via hole, filling the remaining space. Also, the present invention provides a printed circuit board and a manufacturing method thereof that do not require filling an inner via hole with an insulating ink, and forming a conductive layer on the insulating ink. Therefore, the present invention can increase productive capacity and reduce manufacturing cost by simplifying the manufacturing process and reducing the lead time.

### CROSS-REFERENCE TO RELATED APPLICATIONS

This application claims the benefit of Korean Patent Application No. 10-2006-0018219 filed with the Korean Intellectual Property Office on Feb. 24, 2006, the disclosures of which are incorporated herein by reference in their entirety.

### BACKGROUND

1. Technical Field

The present invention relates to a printed circuit board, more specifically to a printed circuit board of which inner via holes (IVH) are fill plated to have no void and a manufacturing method thereof.

2. Description of the Related Art

A printed circuit board (PCB) is manufactured through forming a wire on one side or both sides of a board composed of thermosetting resin, mounting and wiring a semiconductor chip, and integrated circuit or electronic parts on the board, and coating them with an insulating material.

With the arrival of digital- era, an electronic device becomes thinner and smaller, and is expected to have more functions and higher performance. In order to meet such an expectation, there has been attempts to make the printed circuit board multi-layered, miniaturized and highly integrated. Examples of such an attempt are multi-layered substrate manufactured by build-up process, fine wires and via holes, application of stack via structure, etc.

Here, in order to apply the stack via structure, it is necessary that a blind via hole (BVH) and an inner via hole (IVH) be filled. As a method to fill the blind via hole, a plating method has been steadily developed and is currently being applied to a product. Meanwhile, the inner via hole is filled with insulating ink or conductive paste, a plating method has not been applied to the inner via hole.

According to the build-up process, a conductive layer and an insulating layer are sequentially stacked on a core layer.

First, the core layer is drilled to form an inner via hole, and the inner via hole is electroless or electrolytic plated with copper so that layers can communicate therethrough. Here, a void is created in the inner via hole, and therefore an additional process is required to fill the void with insulating ink. After that, through the build-up process, the blind via hole is mounted on the inner via hole or a circuit to have a staggered via or stacked via structure.

The circuit (an internal or external circuit) in each layer of a multi-layered substrate is formed by additive process, subtractive process, semi-additive process, or the like.

The additive process selectively deposits a conductive material on an insulating substrate through the electroless or electrolytic plating, forming a circuit pattern. Depending on whether or not a seed layer for the electrolytic copper plating exists, the additive process is classified into a full-additive process and the semi-additive process.

The subtractive process selectively removes unnecessary portions from an insulating substrate, forming a circuit pattern thereon. This process is also called as a tent-and-etch process since a portion where the circuit pattern is to be formed and a hole are tented and etched with photo resist.

FIG. 1 illustrates a process of forming an internal circuit by the subtractive process. Referring to FIG. 1(a), a core layer 110 is disposed. The core layer 110 may be a copper clad laminate (CCL) composed of an insulating layer 113 formed of epoxy resin and a copper foil 120 laminated on both sides of the insulating layer 113. In the case of a multi-layer substrate, the core layer 110 can further include an inner layer 116 in the insulating layer 113.

Referring to FIGS. 1(b) and (c), the core layer 110 is drilled mechanically to create an inner via hole 130 in a predetermined portion, and a conductive layer 150 is formed on the core layer 110 by the electroless or electrolytic copper plating, allowing layers to communicate through the inner via hole 130. At this time, an unfilled void is generated in the inner via hole 130, and such a void is filled by insulating ink 140.

Referring to FIG. 1(d), cap plating is performed, after filling the inner via hole 130 with the insulating ink 140, to form a plating layer on the inner via hole 130 so that the conductive layer 150 can be electrically connected to a blind via hole that is stacked later on the inner via hole 130.

And, referring to FIGS. 1(e) through (g), a dry film is laminated over the conductive layer 150 and the portion 160 where the cap plating was performed, and is photo-exposed and developed, and is etched in a portion where copper is exposed, thereby forming the internal circuit.

While, in the above description, the inner via hole was filled by the subtractive process, the additive process, semi-additive process, or modified semi-additive process can also be applied in the same manner as described above.

However, a void is created when the inner via hole is filled with the insulating ink, deteriorating electric connection between layers and also increasing manufacturing costs.

In the conventional printed circuit board, a fill plating refers to filling the blind via hole. Generally, the blind via hole is plated to a desired thickness at one time by applying currents having the same current density to its both surfaces. When the same plating method is applied to the inner via hole, the inner via hole is first filled in its middle part. Consequently, the agitation characteristic of the center part of the inner via hole deteriorates, generating the void. Agitation means mixing at least two materials having different chemical or physical properties into a uniform mixture. The agitation characteristic herein refers to the properties that mix ions within the plating solution uniformly. Due to the ingredients contained in a fill plating solution, the plating layer grows inside the inner via hole faster than on near entrances of the inner via hole. Accordingly, a ratio (Hole D) of the thickness of the substrate to the diameter of the inner via hole in the middle part becomes larger, so that the fill plating solution can not flow easily inside the inner via hole, deteriorating the agitation characteristic inside the inner via hole.

FIG. 2 is a picture of an inner via hole that is fill plated by applying the same current to both surfaces of the core layer. FIG. 2(a) shows a case where the core layer is 60 μm thick, and the diameter of the inner via hole is about 65 μm. FIG. 2(b) shows a case where the thickness of the core layer is 100 μm, and the diameter of the inner via hole is about 75 μm. As shown in FIGS. 2(a) and (b), a void is generated in the middle part of the inner via hole.

### SUMMARY

The present invention provides a printed circuit board having an inner via hole that is filled without generating a void, and a manufacturing method thereof.

Also, the present invention provides a printed circuit board and a manufacturing method thereof that can realize stack via structure without an additional process such as cap plating since an inner via hole is completely fill plated.

Also, the present invention provides a printed circuit board and a manufacturing method thereof that do not require filling an inner via hole with an insulating ink, and forming a conductive layer on the insulating ink. Therefore, the present invention can increase productive capacity and reduce manufacturing cost by simplifying the manufacturing process and reducing the lead time.

An aspect of the present invention features a printed circuit board. The board can comprise a core layer in which an inner via hole (IVH) is formed, a first plating layer that closes one entrance of the inner via hole, leaving a remaining space in the inner via hole unfilled; and a second plating layer that closes the other entrance of the inner via hole, filling the remaining space.

The remaining space can be formed in a cone-shape.

Another aspect of the present invention features a method for manufacturing a printed circuit board with an inner via hole. The method can comprise: (a) applying a first current to both surfaces of a core layer having the inner via hole, so that a first plating layer grows centerwardly in an equal rate from all the directions of an inner wall of the inner via hole to close one entrance of the inner via hole, leaving a remaining space the inner via hole unfilled; and (b) applying a second current to fill the remaining space of the inner via hole.

The step (a) can further comprise applying the first current such that two currents having different current densities are each applied to both surfaces of the core layer.

In the step (a), the entrance can be nearer to one of the both surfaces of the core layer to which a denser first current is applied.

In the step (b), the remaining space of the inner via hole can be fill plated.

Additional aspects and advantages of the present general inventive concept will be set forth in part in the description which follows, and in part will be obvious from the description, or may be learned by practice of the general inventive concept.

### BRIEF DESCRIPTION OF THE DRAWINGS

These and other features, aspects, and advantages of the present invention will become better understood with regard to the following description, appended claims, and accompanying drawings where:

FIG. 1 illustrates a process of forming an internal circuit by a subtractive process.

FIG. 2 is a picture of an inner via hole that is fill plated by applying currents having the same current density to both surfaces of a core layer.

FIG. 3 illustrates a fill plating method for filling an inner via hole according to an embodiment of the present invention.

FIG. 4 illustrates a fill plating method for filling an inner via hole according to another embodiment of the present invention.

FIG. 5 is a flowchart of a manufacturing method of a printed circuit board that completely fill plates an inner via hole according to an embodiment of the present invention.

FIGS. 6 to 8 are pictures showing sectional views of a printed circuit board having an inner via hole that is fill plated by a manufacturing method according to an embodiment of the present invention.

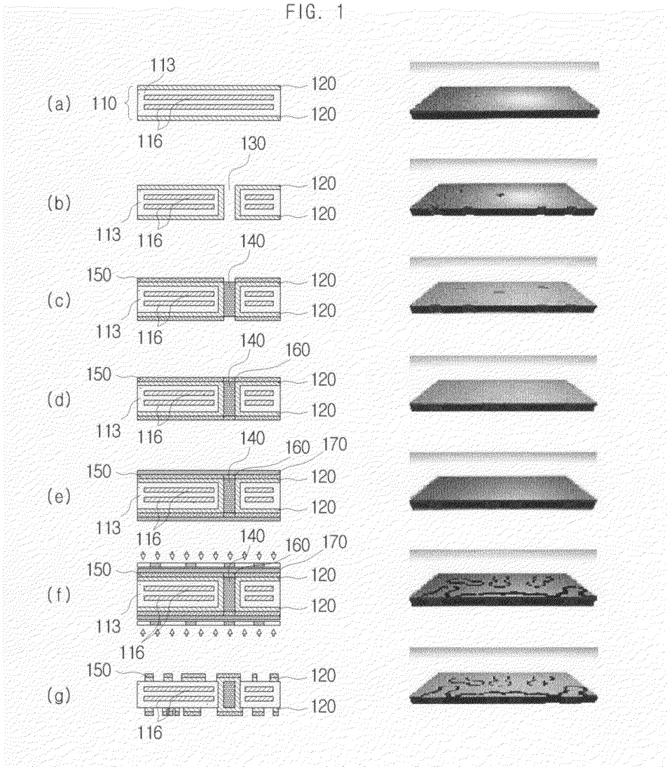

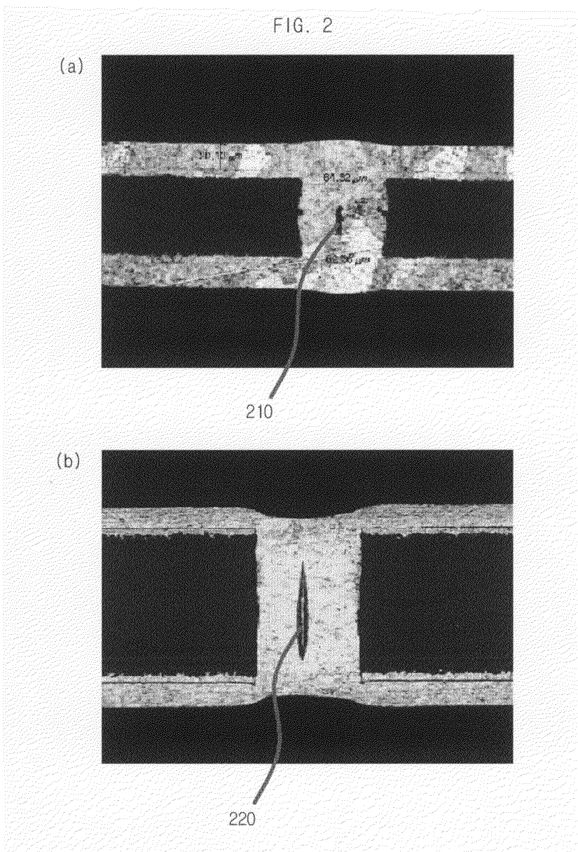

### DETAILED DESCRIPTION

Hereinafter, embodiments of the invention will be described in more detail with reference to the accompanying drawings. In the description with reference to the accompanying drawings, those components are rendered the same reference number that are the same or are in correspondence regardless of the figure number, and redundant explanations are omitted.

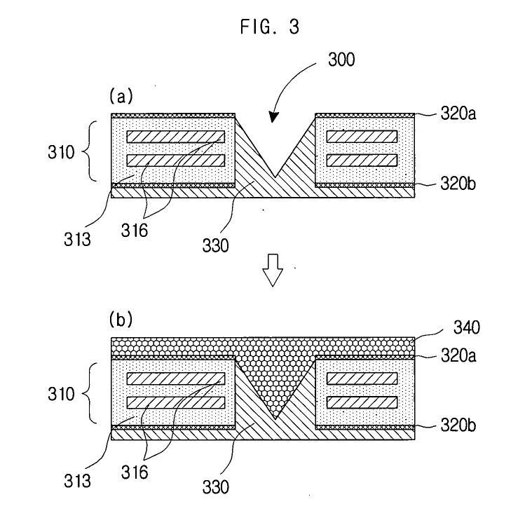

FIG. 3 illustrates a fill plating method for an inner via hole according to an embodiment of the present invention.

Referring to FIG. 3(a), a core layer 310 is a copper clad laminate, which is composed of an insulating layer 313 and a copper foil 320a and 320b laminated on the insulating layer 313. An inner via hole 300 is formed at a predetermined portion of the core layer 310. A mechanical drill or laser drill can be used to form the inner via hole 300. Examples of the laser drill include a CO₂ laser drill and an Nd-YAG laser drill.

A first plating layer 330 is formed by supplying a first current to an upper copper foil 320a and a lower copper foil 320b of the core layer 310. In the following embodiment, the first current is supplied so that no current is applied to the upper copper foil 320a. When currents of the same current density are applied to the upper copper foil 320a and the lower copper foil 320b, a first plated layer grows toward a middle part of the inner via hole 300 so that the middle part is first closed. However, in case a current is applied only to the lower copper foil 320b, the first plating layer first closes a lower entrance of the inner via hole 300.

In case that the first plating layer 330 closes the middle part of the inner via hole 300, the plating solution cannot flow smoothly, deteriorating the agitation characteristic as described above. However, when the lower entrance of the inner via hole 330 is first closed, the plating solution can flow more smoothly, so that ions in the first plating layer 330 can be distributed uniformly. Therefore, no void, which occurs due to a poor agitation, is generated.

Because the first plating layer 330 closes the lower entrance, a remaining space formed in a cone-shape is left unfilled in the inner via hole 300. The remaining space is later fill plated with a second plating layer 340. The cone-shaped remaining space has a similar shape to a blind via hole, which can be completely fill plated by a conventional plating method. Thus, the conventional plating method can also be applied to the cone shaped remaining space. Here, a conductive layer for forming a circuit pattern is formed while the first plating layer 330 is laminated on the lower copper foil 320b.

Referring to FIG. 3(b), a second plating layer 340 is laminated on the upper copper foil 320a, fill plating the remaining space of the inner via hole 300 completely.

The blind via hole is fill plated with a plating solution having a high metal concentration. The plating solution is composed of a polarizer and an accelerant, where the polarizer is absorbed onto the surface of the hole to restrain the plating from growing, and the accelerant is absorbed to an inside wall of the hole to accelerate the growth of the plating. Thus, the first plating layer 330 and the second plating layer 340 completely fills the inner via hole 300 without generating a void, enhancing the electrical connection between layers.

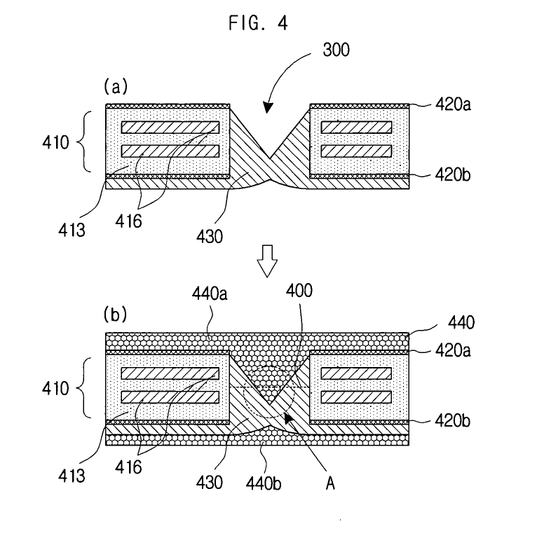

FIG. 4 illustrates a fill plating method of an inner via hole according to another embodiment of the present invention.

Referring to FIG. 4(a), a first plating layer is formed by applying a first current to an upper copper foil 420a and a lower copper foil 420b of the core layer 410. In the following embodiment, the first current is applied such that a current of a higher current density is applied to the lower copper foil 420b than the upper copper foil 420a. When currents having an equal current density are applied to the upper copper foil 420a and the lower copper foil 420b, the first plating layer grows toward a middle part the inner via hole 300 to close the middle part. However, in the above case, the first plating layer closes a lower part of the inner via hole 300.

Compared to the case where the first plated layer 430 closes the middle part of the inner via hole 300, when the first plating layer 430 closes the lower part, the plating solution flows more smoothly, so that no void is created. After the first plating layer 430 closes the lower part of the inner via hole 300, two cone-shaped remaining spaces are left unfilled over and below the first plating layer. Each cone-shaped remaining space is similar to a blind via hole, which can be fill plated by a conventional plating method. Therefore, the conventional plating method can be applied to fill the cone-shaped remaining spaces. Here, a conductive layer for forming a circuit pattern is formed while the first plating layer 430 is laminated on the upper copper foil 420a and the lower copper foil 420b.

Referring to FIG. 4(b), the remaining spaces, having a similar shape to the blind via hole, are completely filled. Consequently, the inner via hole is completely filled with the first plating layer 430 and the second plating layer 340 without generating a void, which in turn enhances the connection between layers.

According to two embodiments as illustrated in FIGS. 3 and 4, the inner via hole 300 is fill plated with a conductive material, so that the cap plating process is not necessary. Also, the stack via structure, in which the blind via hole is stacked on the inner via hole 300 without an additional process, can be applied to the printed circuit board. Furthermore, the present invention is excellent in heat radiation, and signal transmission.

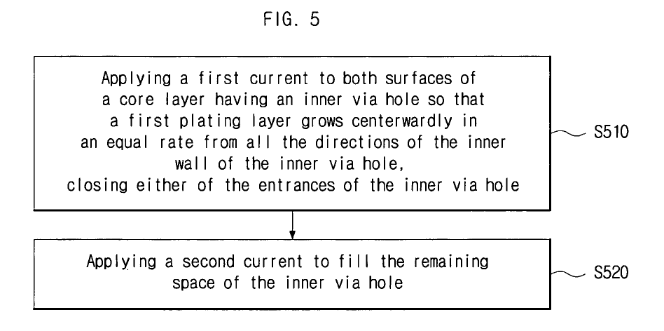

FIG. 5 is a flowchart showing a manufacturing method of a printed circuit board according to an embodiment of the present invention, by which an inner via hole can be completely fill plated.

At step S510, a first current is supplied to both upper and lower surfaces of a core layer having an inner via hole. With the first current, a first plating layer grows inwardly in an equal rate from all the directions of the inner wall of the inner via, closing the inner via hole. The first current is applied such that a current is applied either of both surfaces. Otherwise, the first current can be applied such that currents having different current densities are applied to the upper and lower surfaces of the core layer. The first plating layer closes a part of the inner via hole which is near the surface where the denser current is applied, without generating a void. Consequently, a cone-shaped remaining space is left unfilled in the inner via hole.

At step S520, a second current is applied to the both surfaces of the core layer in order to fill plate the cone-shaped space. As mentioned above, since the cone-shaped remaining space is in form of the blind via hole, the conventional plating method for the blind via hole can be used to fill the cone-shaped remaining space completely.

The present invention can also be applied to fill an inner via hole formed by not only the subtractive process as described above but also the additive process, the semi-additive process, the modified semi-additive process, etc.

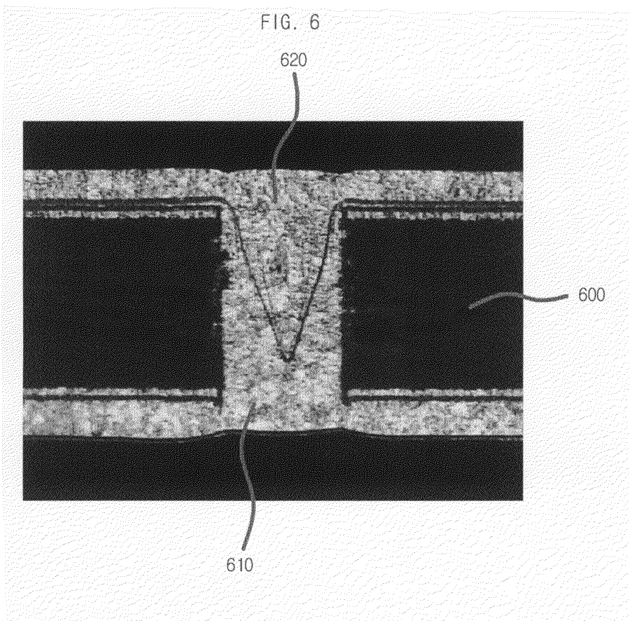

FIGS. 6 to 8 are pictures of a printed circuit board manufactured by embodiments of the present invention, thereby showing no void in its inner via hole.

Referring to FIG. 6, at first, a first plated player 610 is formed in an inner via hole of the core layer 600, leaving a cone-shaped remaining space (a remaining space having a cross section in form of V as shown in FIG. 6) in the rest of the inner via hole. Then, a second plated layer 620 completely fills the remaining space without generating a void.

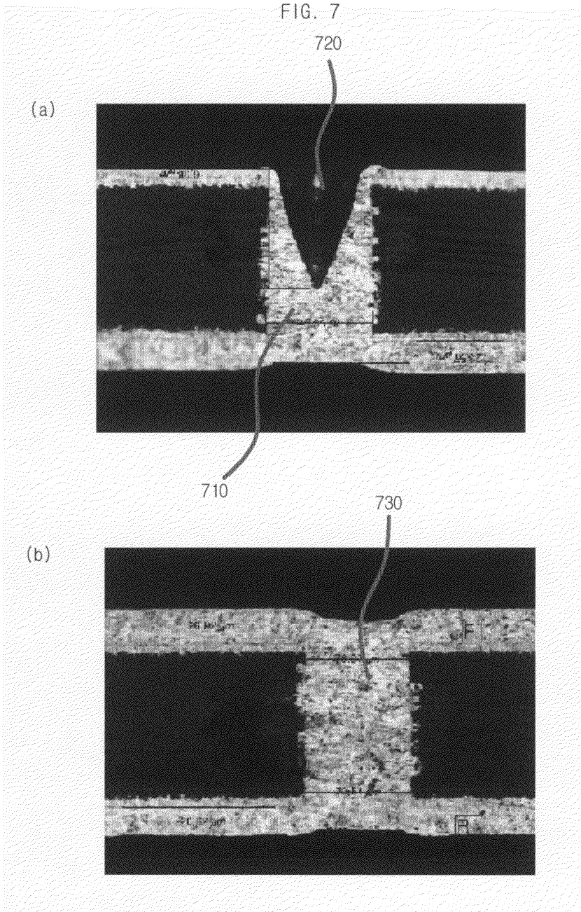

FIG. 7 is a picture of an inner via hole of a core layer filled by a plating layer, where the thickness of the core layer is 100 μm, the diameter of the inner via hole is 75 μm, and the thickness of the plating layer on the surface of the core layer is 26 μm. FIG. 7 confirms the illustration of FIG. 3 through an experiment. Referring to FIG. 7(a), a first plating layer 710 is first plated, forming a remaining space 720 in the inner via hole. Then, the remaining space 720 is completely fill plated by a second plating layer 730, generating no void.

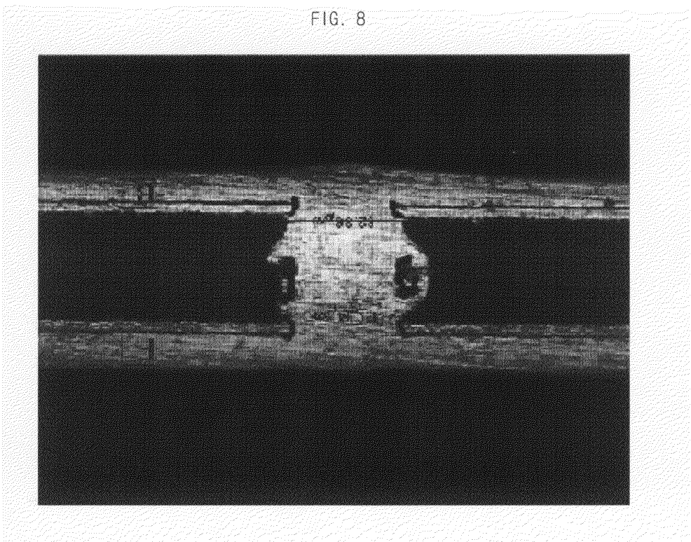

FIG. 8 is a picture of an inner via hole of a core layer filled by a plating layer, where the thickness of the core layer is 60 μm, the diameter of the inner via hole is 65 μm, and the thickness of the plating layer on the surface of the core layer is 20 μm or less In this case also, no void is shown.

While the invention has been described with reference to the disclosed embodiments, it is to be appreciated that those skilled in the art can change or modify the embodiments without departing from the scope and spirit of the invention or its equivalents as stated below in the claims.

What is claimed is:

1. A printed circuit board comprising:
a core layer in which an inner via hole (IVH) is formed;
a first plating layer that closes one entrance of the inner via hole, leaving a remaining space in the inner via hole unfilled; and
a second plating layer that closes the other entrance of the inner via hole, filling the remaining space.

2. The printed circuit board of claim 1, wherein the remaining space is formed in a cone-shape.

3. A method for manufacturing a printed circuit board with an inner via hole, the method comprising:
(a) applying a first current to both surfaces of a core layer having the inner via hole, so that a first plating layer grows centerwardly in an equal rate from all the directions of an inner wall of the inner via hole to close one entrance of the inner via hole, leaving a remaining space the inner via hole unfilled; and
(b) applying a second current to fill the remaining space of the inner via hole.

4. The method of claim 3, wherein the step (a) further comprises applying the first current such that two currents having different current densities are each applied to both surfaces of the core layer.

5. The method of claim 4, wherein, in the step (a), the entrance is nearer to one of the both surfaces of the core layer to which a denser first current is applied.

6. The method of claim 3, wherein, in the step (b), the remaining space of the inner via hole is fill plated.
